(19) United States
(12) Patent Application Publication
(10) Pub. No.: US 2025/0056991 A1
(43) Pub. Date: Feb. 13, 2025

(54) DISPLAY DEVICE

(71) Applicant: Samsung Display Co., LTD., Yongin-si (KR)

(72) Inventors: YEONG-GYU KIM, Yongin-si (KR); SEMYUNG KWON, Yongin-si (KR); CHANG-YEOL LEE, Yongin-si (KR); WOONGHEE JEONG, Yongin-si (KR); YOUNGJIN CHO, Yongin-si (KR)

(21) Appl. No.: 18/796,111

(22) Filed: Aug. 6, 2024

(30) Foreign Application Priority Data
Aug. 7, 2023 (KR) 10-2023-0103065

(51) Int. Cl. H10K 59/131; H10K 59/124

(52) U.S. Cl. CPC H10K 59/131; H10K 59/124

(57) ABSTRACT

A display device includes a pixel circuit part including a first oxide semiconductor layer, a first gate driver electrically connected to the pixel circuit part, and including a second oxide semiconductor layer at a same layer as the first oxide semiconductor layer, and a first line part electrically connected to the first gate driver, and defining at least one first dummy contact hole adjacent to the second oxide semiconductor layer.

### CROSS-REFERENCE TO RELATED APPLICATION

The present application claims priority to, and the benefit of, Korean Patent Application No. 10-2023-0103065, filed on Aug. 7, 2023, in the Korean Intellectual Property Office, the entire disclosure of which is incorporated herein by reference.

### BACKGROUND

### 1. Field

The present disclosure relates generally to a display device.

### 2. Description of the Related Art

A display device includes a display part and a driver, and the driver generates a driving signal, and provides the driving signal to the display part. For the driver to generate the drive signal, the driver includes a transistor, and a semiconductor layer of the transistor may be a silicon semiconductor (amorphous silicon, polycrystalline silicon, etc.) or an oxide semiconductor.

Recently, to simplify the circuit structure of the driver and to reduce power consumption, the development of a driver with a CMOS structure (complementary metal oxide silicon structure) including a transistor formed of a silicon semiconductor and a transistor formed of an oxide semiconductor has been actively developed.

### SUMMARY

Embodiments provide a display device.

A display device according to one or more embodiments may include a pixel circuit part including a first oxide semiconductor layer, a first gate driver electrically connected to the pixel circuit part, and including a second oxide semiconductor layer at a same layer as the first oxide semiconductor layer, and a first line part electrically connected to the first gate driver, and defining at least one first dummy contact hole adjacent to the second oxide semiconductor layer.

The first line part may include at least one first clock line overlapping the first dummy contact hole, and for providing a clock signal to the first gate driver.

The display device may further include a second gate driver electrically connected to the pixel circuit part, and including a third oxide semiconductor layer at a same layer as the second oxide semiconductor layer.

The display device may further include a second line part adjacent to the second gate driver, electrically connected to the second gate driver, and defining at least one second dummy contact hole adjacent to the third oxide semiconductor layer.

The second line part may include at least one second clock line overlapping the second dummy contact hole overlaps the second clock line, and for providing a clock signal to the second gate driver.

The first gate driver may further include at least one first inorganic insulating layer under the second oxide semiconductor layer, and at least one second inorganic insulating layer above the second oxide semiconductor layer, wherein the first inorganic insulating layer and the second inorganic insulating layer extend to the first line part, and wherein the first dummy contact hole penetrates the first and second inorganic insulating layers overlapping the first line part.

The pixel circuit part further includes a first silicon semiconductor layer under the first oxide semiconductor layer, wherein the first gate driver further includes a second silicon semiconductor layer under the second oxide semiconductor layer, and wherein the first line part includes an etch stopper at a same layer as the second silicon semiconductor layer.

The first dummy contact hole may expose the etch stopper.

The first line part may further include at least one first clock line contacting the etch stopper through the first dummy contact hole, and for providing a clock signal to the first gate driver.

The first gate driver may be divided into first stages, wherein one or more contact holes penetrating the first and second inorganic insulating layers is defined in the first stages, and wherein a number of the first dummy contact holes per unit area of the first line part corresponds to a number of the contact holes per unit area of one of the first stages.

The number of the first dummy contact holes per unit area of the first line part may be about 70% to about 130% of the number of the contact holes per unit area of each of the first stages.

The display device may further include a second gate driver divided into second stages, and a second line part electrically connected to the second gate driver, wherein the first inorganic insulating layer and the second inorganic insulating layer extend to the second gate driver and to the second line part, wherein at least one second dummy contact hole is defined in the second line part, and penetrates the first and second inorganic insulating layers overlapping the second line part, and wherein a number of the second dummy contact holes per unit area of the second line part corresponds to the number of the contact holes per unit area of each of the first stages.

The first line part may include a straight portion, and a curved portion defining a third dummy contact hole.

The first gate driver may further include at least one first inorganic insulating layer under the second oxide semiconductor layer, and at least one second inorganic insulating layer above the second oxide semiconductor layer, wherein the first inorganic insulating layer and the second inorganic insulating layer extend to the first line part, and wherein the third dummy contact hole penetrates the first and second inorganic insulating layers overlapping the curved portion.

The first gate driver may be divided into first stages, wherein at least one contact hole penetrating the first and second inorganic insulating layers is defined in the first stages, and wherein a number of the third dummy contact holes per unit area of the curved portion corresponds to the number of the contact holes per unit area of the first stages.

The pixel circuit part may further include a first silicon semiconductor layer under the first oxide semiconductor layer, wherein the first gate driver further includes a second silicon semiconductor layer at a same layer as the first silicon semiconductor layer.

The display device may further include a second gate driver electrically connected to the pixel circuit part, and including a third oxide semiconductor layer at a same layer as the second oxide semiconductor layer, wherein the first gate driver is configured to provide a gate compensation signal to the pixel circuit part, and wherein the second gate driver is configured to provide a gate bias signal to the pixel circuit part.

The display device may further include a second gate driver electrically connected to the pixel circuit part, and including a third oxide semiconductor layer at a same layer as the second oxide semiconductor layer, wherein the first gate driver is configured to provide a gate compensation signal to the pixel circuit part, and wherein the second gate driver is configured to provide an emission management signal to the pixel circuit part.

A display device according to one or more other embodiments may include a first oxide semiconductor layer overlapping a display area, a second oxide semiconductor layer at a same layer as the first oxide semiconductor layer, and overlapping a circuit area adjacent to the display area, and at least one inorganic insulating layer overlapping the circuit area, and a line area adjacent to the circuit area and defining at least one dummy contact hole, and wherein the dummy contact hole is adjacent to the second oxide semiconductor layer, and is defined by the inorganic insulating layer.

The display device may further include at least one clock line overlapping the line area, and overlapping the dummy contact hole.

The inorganic insulating layer may include a first inorganic insulating layer under the second oxide semiconductor layer, and a second inorganic insulating layer above the second oxide semiconductor layer, wherein the first inorganic insulating layer and the second inorganic insulating layer extend to the line area, and wherein the dummy contact hole penetrates the first and second inorganic insulating layers overlapping the line area.

The display device may further include a first silicon semiconductor layer overlapping the display area, and under the first oxide semiconductor layer, a second silicon semiconductor layer overlapping the circuit area, and under the second oxide semiconductor layer, and an etch stopper overlapping the line area, and at a same layer as the second silicon semiconductor layer.

The dummy contact hole may expose the etch stopper.

The display device may further include at least one clock line overlapping the line area, and contacting the etch stopper through the dummy contact hole.

Therefore, a display device according to one or more embodiments of the present disclosure may include a gate driver and a line part. The gate driver may include a silicon semiconductor layer and an oxide semiconductor layer, and the line part may provide a clock signal to the gate driver.

A dummy contact hole may be formed in the line part. As the dummy contact hole is positioned adjacent to the oxide semiconductor layer, hydrogen contained in the inorganic insulating layer may diffuse through the dummy contact hole. Accordingly, the hydrogen may not diffuse into the oxide semiconductor layer, the negative shift of the threshold voltage of the NMOS transistor formed from the oxide semiconductor layer may be reduced or prevented, and the reliability of the NMOS transistor may be improved.

### BRIEF DESCRIPTION OF DRAWINGS

The accompanying drawings, which are included to provide a further understanding of the present disclosure, and are incorporated in and constitute a part of this specification, illustrate embodiments of the present disclosure together with the description.

FIG. 1 is a block diagram illustrating a display device according to one or more embodiments of the present disclosure.

FIG. 2 is a circuit diagram illustrating a pixel circuit part included in the display device of FIG. 1.

FIG. 3 is a circuit diagram illustrating a first gate driver included in the display device of FIG. 1.

FIG. 4 is a circuit diagram illustrating a second gate driver included in the display device of FIG. 1.

FIG. 5 is a circuit diagram illustrating a third gate driver included in the display device of FIG. 1.

FIG. 6 is a plan view illustrating the display device of FIG. 1.

FIG. 7 is a cross-sectional view illustrating a pixel structure included in the display device of FIG. 6.

FIG. 8 is a cross-sectional view illustrating a first gate driver included in the display device of FIG. 6.

FIG. 9 is a cross-sectional view illustrating a second gate driver included in the display device of FIG. 6.

FIG. 10 is an enlarged view of a straight portion of FIG. 6.

FIG. 11 is a cross-sectional view taken along the line I-I′ of FIG. 10.

FIG. 12 is a cross-sectional view taken along the line II-II′ of FIG. 10.

FIG. 13 is a cross-sectional view taken along the line III-III′ of FIG. 10.

FIG. 14 is an enlarged view of a curved portion of FIG. 6.

FIGS. 15 to 20 are cross-sectional views illustrating a method of manufacturing the display device of FIG. 6.

FIG. 21 is a plan view illustrating a display device according to one or more other embodiments of the present disclosure.

FIG. 22 is an enlarged view of a straight portion of FIG. 21.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

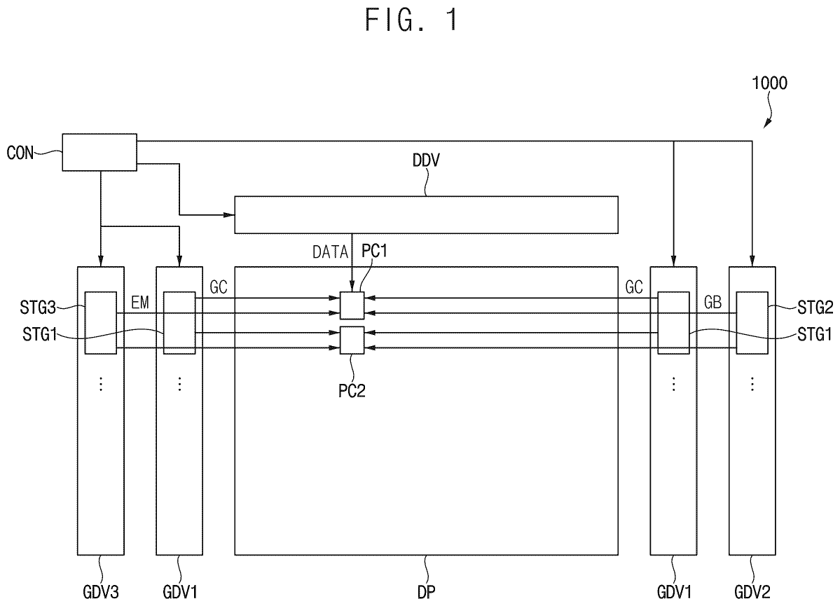

FIG. 1 is a block diagram illustrating a display device according to one or more embodiments of the present disclosure.

Referring to FIG. 1, the display device 1000 according to one or more embodiments of the present disclosure may include a display part DP, a data driver DDV, a first gate driver GDV1, a second gate driver GDV2, a third gate driver GDV3, and a controller CON.

A plurality of pixel circuit parts may be formed in the display part DP. For example, the pixel circuit parts may include a first pixel circuit part PC1 and a second pixel circuit part PC2. Each of the first and second pixel circuit parts PC1 and PC2 may electrically connected to the data driver DDV, the first gate driver GDV1, the second gate driver GDV2, and the third gate driver GDV3. Each of the first and second pixel circuit parts PC1 and PC2 may receive a data voltage DATA, a gate compensation signal GC, a gate bias signal GB, and an emission management signal EM.

The data driver DDV may generate the data voltage DATA by the controller CON.

The first gate driver GDV1 may generate the gate compensation signal GC according to control of the controller CON. The gate compensation signal GC may include a gate-on voltage that turns on a transistor, and a gate-off voltage that turns off the transistor.

The first gate driver GDV1 may include first stages STG1. The first stages STG1 may sequentially output the gate compensation signal GC. In one or more embodiments, each of the first stages STG1 may output the gate compensation signal GC to the first and second pixel circuit parts PC1 and PC2.

The second gate driver GDV2 may generate the gate bias signal GB according to control of the controller CON. The gate bias signal GB may include the gate-on voltage and the gate-off voltage.

The second gate driver GDV2 may include second stages STG2. The second stages STG2 may sequentially output the gate bias signal GB. In one or more embodiments, each of the second stages STG2 may output the gate bias signal GB to the first and second pixel circuit parts PC1 and PC2.

The third gate driver GDV3 may generate the emission management signal EM according to control of the controller CON. The emission management signal EM may include the gate-on voltage and the gate-off voltage.

The third gate driver GDV3 may include third stages STG3. The third stages STG3 may sequentially output the emission management signal EM. In one or more embodiments, each of the third stages STG3 may output the emission management signal EM to the first and second pixel circuit parts PC1 and PC2.

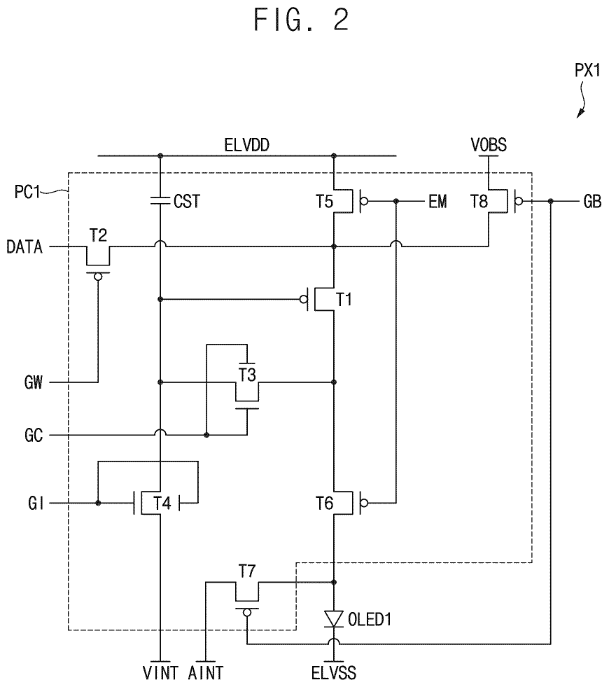

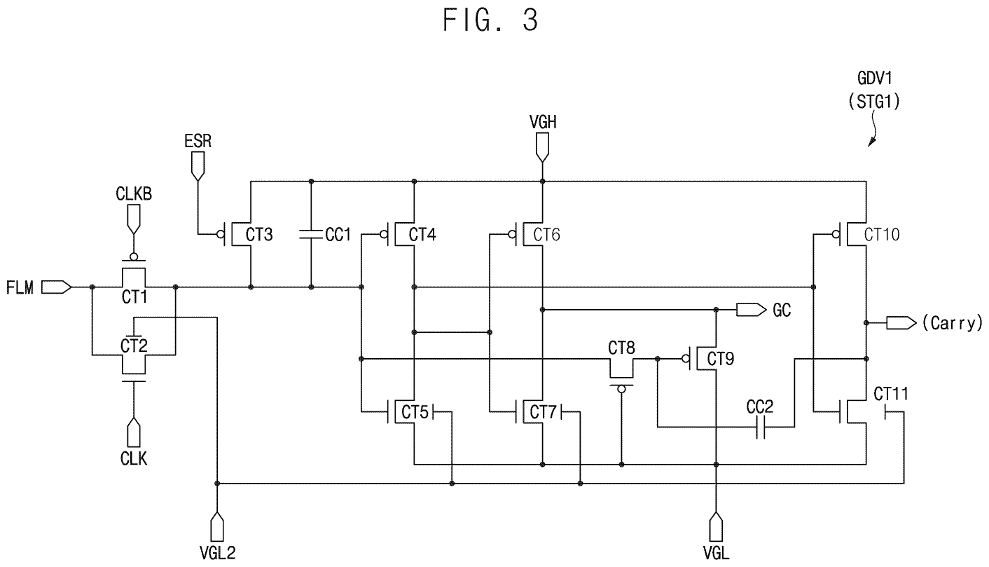

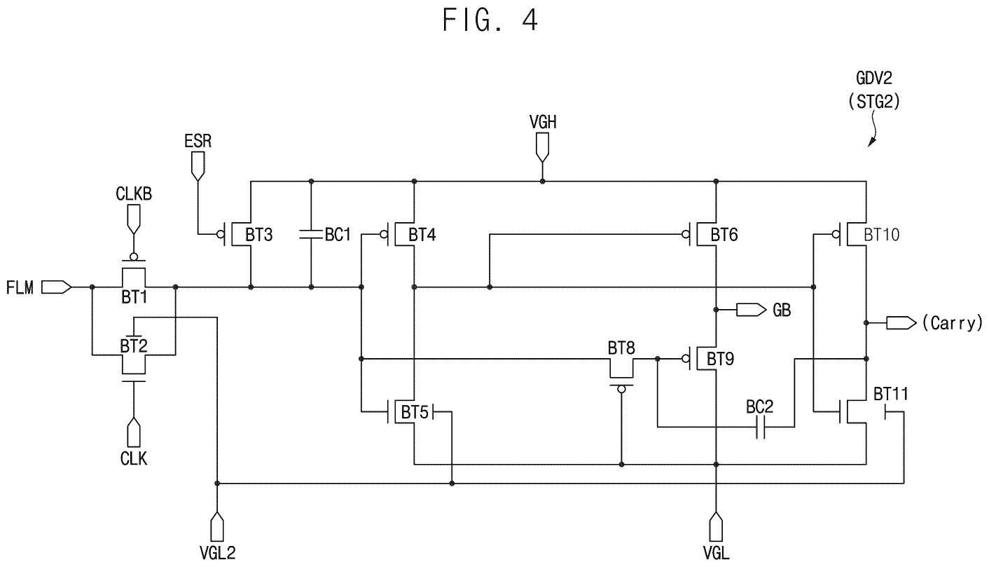

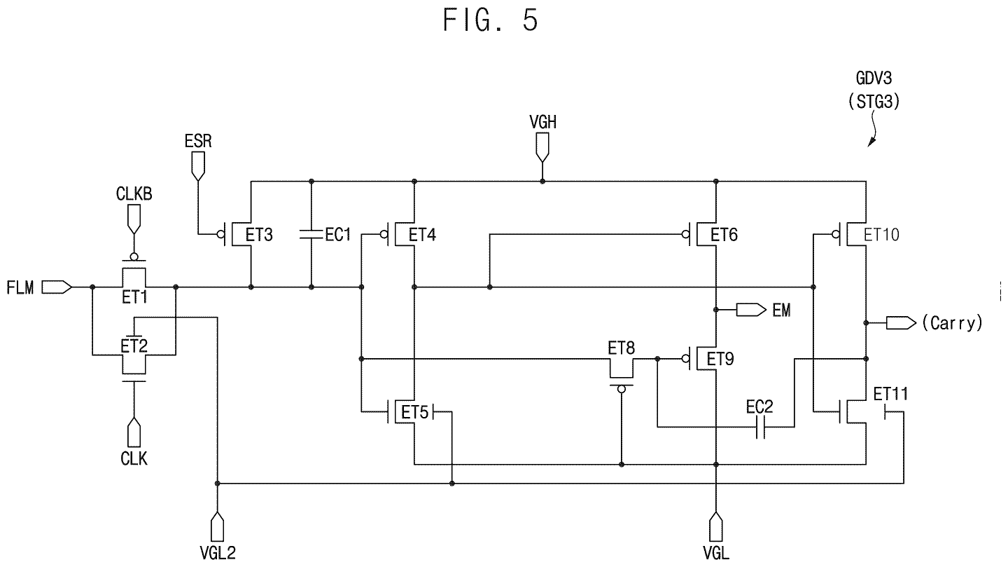

FIG. 2 is a circuit diagram illustrating a pixel circuit part included in the display device of FIG. 1. FIG. 3 is a circuit diagram illustrating a first gate driver included in the display device of FIG. 1. FIG. 4 is a circuit diagram illustrating a second gate driver included in the display device of FIG. 1. FIG. 5 is a circuit diagram illustrating a third gate driver included in the display device of FIG. 1.

Referring to FIG. 2, a first pixel structure PX1 may include the first pixel circuit part PC1 and the first light-emitting diode OLED1. The first pixel circuit part PC1 may generate a driving current corresponding to the data voltage DATA, and the first light-emitting diode OLED1 may emit light corresponding to the driving current. A second pixel structure PX2 may have substantially the same circuit structure as the first pixel structure PX1.

The first pixel circuit part PC1 may include a first transistor T1, a second transistor T2, a third transistor T3, a fourth transistor T4, a fifth transistor T5, a sixth transistor T6, a seventh transistor T7, an eighth transistor T8, and a storage capacitor CST.

The storage capacitor CST may include a first terminal and a second terminal. The first terminal of the storage capacitor CST may be connected to the first transistor T1, and the second terminal of the storage capacitor CST may receive a driving voltage ELVDD. The storage capacitor CST may maintain a voltage level of the gate terminal of the first transistor T1 during the deactivation period of a gate write signal GW.

The first transistor T1 may include a gate terminal, a first terminal, and a second terminal. The gate terminal of the first transistor T1 may be connected to the first terminal of the storage capacitor CST. The first terminal of the first transistor T1 may be connected to the second transistor T2 and may receive the data voltage DATA. The second terminal of the first transistor T1 may be connected to the sixth transistor T6. The first transistor T1 may generate the driving current based on a voltage difference between the gate terminal and the first terminal. For example, the first transistor T1 may be referred to as a driving transistor.

The second transistor T2 may include a gate terminal, a first terminal, and a second terminal. The gate terminal of the second transistor T2 may receive the gate write signal GW. The second transistor T2 may be turned on or off in response to the gate write signal GW. For example, if the second transistor T2 is a PMOS transistor, the second transistor T2 may be turned off if the gate write signal GW has a positive voltage level, and may be turned on if the gate write signal GW has a negative voltage level. The first terminal of the second transistor T2 may receive the data voltage DATA. The second terminal of the second transistor T2 may provide the data voltage DATA to the first terminal of the first transistor T1 during the period in which the second transistor T2 is turned on. For example, the second transistor T2 may be referred to as a switching transistor.

The third transistor T3 may include a gate terminal, a lower gate terminal, a first terminal, and a second terminal. The gate terminal and the lower gate terminal of the third transistor T3 may receive the gate compensation signal GC. The first terminal of the third transistor T3 may be connected to the second terminal of the first transistor T1. The second terminal of the third transistor T3 may be connected to the gate terminal of the first transistor T1. The third transistor T3 may be turned on or off in response to the gate compensation signal GC. For example, if the third transistor T3 is an NMOS transistor, the third transistor T3 may be turned on if the gate compensation signal GC has a positive voltage level, and may be turned off if the gate compensation signal GC has a negative voltage level. During a period in which the third transistor T3 is turned on in response to the gate compensation signal GC, the third transistor T3 may diode-connect the first transistor T1. Accordingly, the third transistor T3 may compensate for a threshold voltage of the first transistor T1. For example, the third transistor T3 may be referred to as a compensation transistor.

The fourth transistor T4 may include a gate terminal, a lower gate terminal, a first terminal, and a second terminal. The gate terminal and the lower gate terminal of the fourth transistor T4 may receive a gate initialization signal GI. The first terminal of the fourth transistor T4 may be connected to the gate terminal of the first transistor T1. The second terminal of the fourth transistor T4 may receive a gate initialization voltage VINT. The fourth transistor T4 may be turned on or off in response to the gate initialization signal GI. For example, if the fourth transistor T4 is an NMOS transistor, the fourth transistor T4 may be turned on if the gate initialization signal GI has a positive voltage level, and may be turned off if the gate initialization signal GI has a negative voltage level. During the period in which the fourth transistor T4 is turned on by the gate initialization signal GI, the gate initialization voltage VINT may be provided to the gate terminal of the first transistor T1. Accordingly, the fourth transistor T4 may initialize the gate terminal of the first transistor T1 to the gate initialization voltage VINT. For example, the fourth transistor T4 may be referred to as a gate initialization transistor.

The fifth transistor T5 may include a gate terminal, a first terminal, and a second terminal. The gate terminal of the fifth transistor T5 may receive the emission management signal EM. The first terminal of the fifth transistor T5 may receive the driving voltage ELVDD. The second terminal of the fifth transistor T5 may be connected to the first transistor T1. If the fifth transistor T5 is turned on in response to the emission management signal EM, the fifth transistor T5 may provide the driving voltage ELVDD to the first transistor T1.

The sixth transistor T6 may include a gate terminal, a first terminal, and a second terminal. The gate terminal of the sixth transistor T6 may receive the emission management signal EM. The first terminal of the sixth transistor T6 may be connected to the first transistor T1. The second terminal of the sixth transistor T6 may be connected to the first light-emitting diode OLED1. If the sixth transistor T6 is turned on in response to the emission management signal EM, the sixth transistor T6 may provide the driving current to the first light-emitting diode OLED1.

The seventh transistor T7 may include a gate terminal, a first terminal, and a second terminal. The gate terminal of the seventh transistor T7 may receive the gate bias signal GB. The first terminal of the seventh transistor T7 may be connected to the first light-emitting diode OLED1. The second terminal of the seventh transistor T7 may receive an anode initialization voltage AINT. If the seventh transistor T7 is turned on in response to the gate bias signal GB, the seventh transistor T7 may provide the anode initialization voltage AINT to the first light-emitting diode OLED1. Accordingly, the seventh transistor T7 may initialize the first terminal of the first light-emitting diode OLED1 to the anode initialization voltage AINT. For example, the seventh transistor T7 may be referred to as an anode initialization transistor.

The eighth transistor T8 may include a gate terminal, a first terminal, and a second terminal. The gate terminal of the eighth transistor T8 may receive the gate bias signal GB. The first terminal of the eighth transistor T8 may be provided with a bias voltage VOBS. The second terminal of the eighth transistor T8 may be connected to the first terminal of the first transistor T1. If the eighth transistor T8 is turned on in response to the gate bias signal GB, the eighth transistor T8 may transfer the bias voltage VOBS to the first transistor T1. The bias voltage VOBS may be about 5V to about 6V, similar to the data voltage of black grayscale. Accordingly, in low-frequency driving, deterioration of the first transistor T1 may be reduced or prevented.

The first light-emitting diode OLED1 may include a first terminal and a second terminal. The first terminal of the first light-emitting diode OLED1 may be connected to the sixth transistor T6, and the second terminal may be provided with a common voltage ELVSS. The first light-emitting diode OLED1 may emit light corresponding to the driving current.

In one or more embodiments, the first, second, fifth, sixth, seventh, and eighth transistors T1, T2, T5, T6, T7, and T8 may be PMOS transistors, and the third and fourth transistors T3 and T4 may be NMOS transistors.

Referring to FIG. 3, the first gate driver GDV1 may include the first stages STG1. Each of the first stages STG1 may include a first compensation circuit capacitor CC1, a second compensation circuit capacitor CC2, and first to eleventh compensation circuit transistors CT1, CT2, CT3, CT4, CT5, CT6, CT7, CT8, CT9, CT10, and CT11. The first gate driver GDV1 may receive a start signal FLM, a clock signal(s) CLK and CLKB, a gate high voltage VGH, a gate low voltage(s) VGL and VGL2, and a reset signal ESR, and may output the gate compensation signal GC.

In one or more embodiments, the first, third, fourth, sixth, eighth, ninth, and tenth compensation circuit transistors CT1, CT3, CT4, CT6, CT8, CT9, and CT10 may be PMOS transistors, and the second, fifth, seventh, and eleventh compensation circuit transistors CT2, CT5, CT7, and CT11 may be NMOS transistors.

Referring to FIG. 4, the second gate driver GDV2 may include the second stages STG2. Each of the second stages STG2 may include a first bias circuit capacitor BC1, a second bias circuit capacitor BC2, and first to sixth and eighth to eleventh bias circuit transistors BT1, BT2, BT3, BT4, BT5, BT6, BT8, BT9, BT10, and BT11. The second gate driver GDV2 may receive a start signal FLM, a clock signal(s) CLK and CLKB, a gate high voltage VGH, a gate low voltage(s) VGL and VGL2, and a reset signal ESR, and may output the gate bias signal GB.

In one or more embodiments, the first, third, fourth, sixth, eighth, ninth, and tenth bias circuit transistors BT1, BT3, BT4, BT6, BT8, BT9, and BT10 may be PMOS transistors, and the second, fifth, and eleventh bias circuit transistors BT2, BT5, and BT11 may be NMOS transistors.

Referring to FIG. 5, the third gate driver GDV3 may include the third stages STG3. Each of the third stages STG3 may include a first light-emitting circuit capacitor EC1, a second light-emitting circuit capacitor EC2, and first to sixth and eighth to eleventh light-emitting circuit transistors ET1, ET2, ET3, ET4, ET5, ET6, ET8, ET9, ET10, and ET11. The third gate driver GDV3 may receive a start signal FLM, a clock signal(s) CLK and CLKB, a gate high voltage VGH, a gate low voltage(s) VGL and VGL2, and a reset signal ESR, and may output the emission management signal EM.

In one or more embodiments, the first, third, fourth, sixth, eighth, ninth, and tenth light-emitting circuit transistors ET1, ET3, ET4, ET6, ET8, ET9, and ET10 may be PMOS transistors, and the second, fifth, and eleventh light-emitting circuit transistors ET2, ET5, and ET11 may be NMOS transistors.

In one or more embodiments, the second gate driver GDV2 and the third gate driver GDV3 may have substantially the same circuit structure.

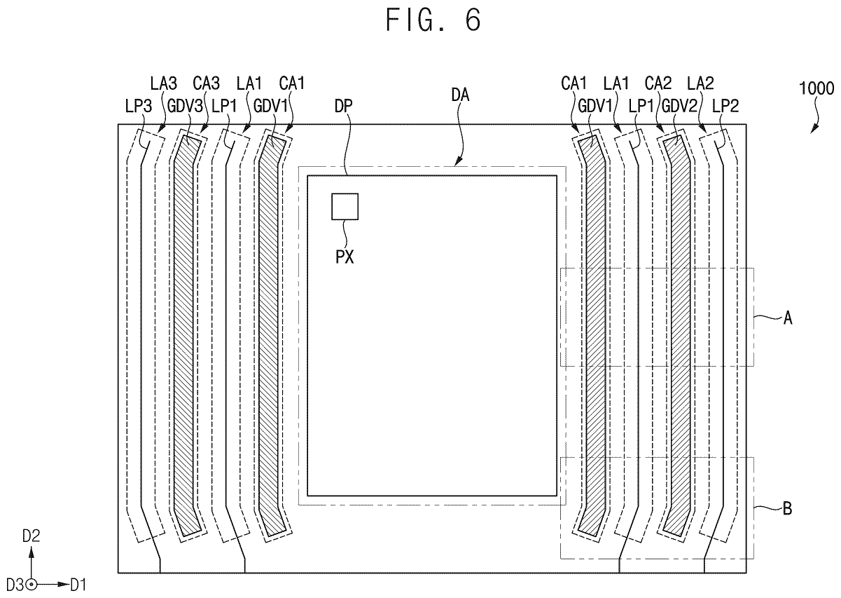

FIG. 6 is a plan view illustrating the display device of FIG. 1.

Referring to FIG. 6, the display device 1000 may be divided into a display area DA and a non-display area, and the non-display area may include a first circuit area CA1, a second circuit area CA2, a third circuit area CA3, a first line area LA1, a second line area LA2, and a third line area LA3.

The display part DP including a pixel structure PX may be located in the display area DA. The first circuit area CA1 may be adjacent to the display area DA, and the first gate driver GDV1 may be located in the first circuit area CA1. In one or more embodiments, as shown in FIG. 6, the first gate driver GDV1 may be adjacent to the left and right sides of the display part DP, respectively.

The first line area LA1 may be adjacent to the first circuit area CA1, and a first line part LP1 may be located in the first line area LA1. The first line part LP1 may be electrically connected to the first gate driver GDV1.

The second circuit area CA2 may be adjacent to the first line area LA1 located on the right side in a first direction D1, and the second gate driver GDV2 may be located in the second circuit area CA2.

The second line area LA2 may be adjacent to the second circuit area CA2 in the first direction D1, and a second line part LP2 may be located in the second line area LA2. The second line part LP2 may be electrically connected to the second gate driver GDV2.

The third circuit area CA3 may be adjacent to the first line area LA1 located on the left in a direction opposite to the first direction D1, and the third gate driver GDV3 may be located in the third circuit area CA3.

The third line area LA3 may be adjacent to the third circuit area CA3 in a direction opposite to the first direction D1, and a third wiring part LP3 may be located in the third line area LA3. The third wiring part LP3 may be electrically connected to the third gate driver GDV3.

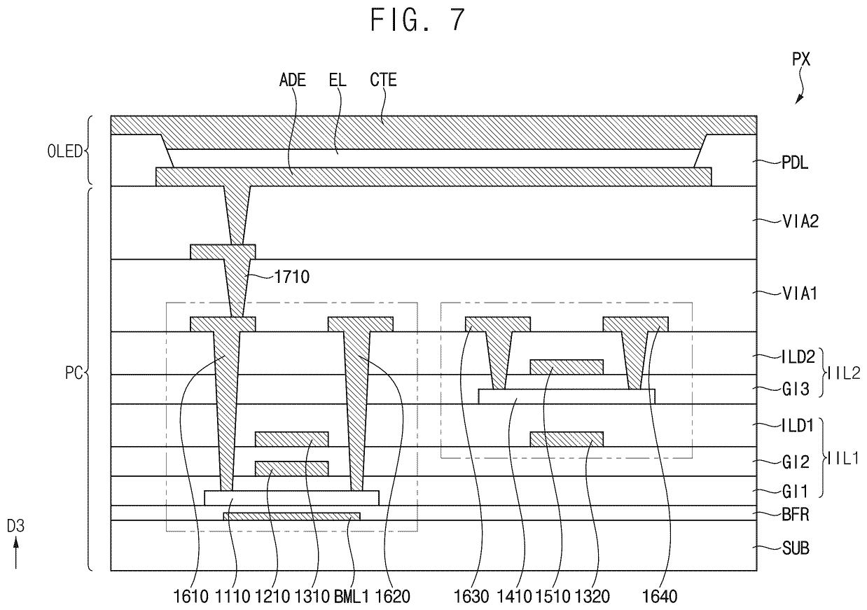

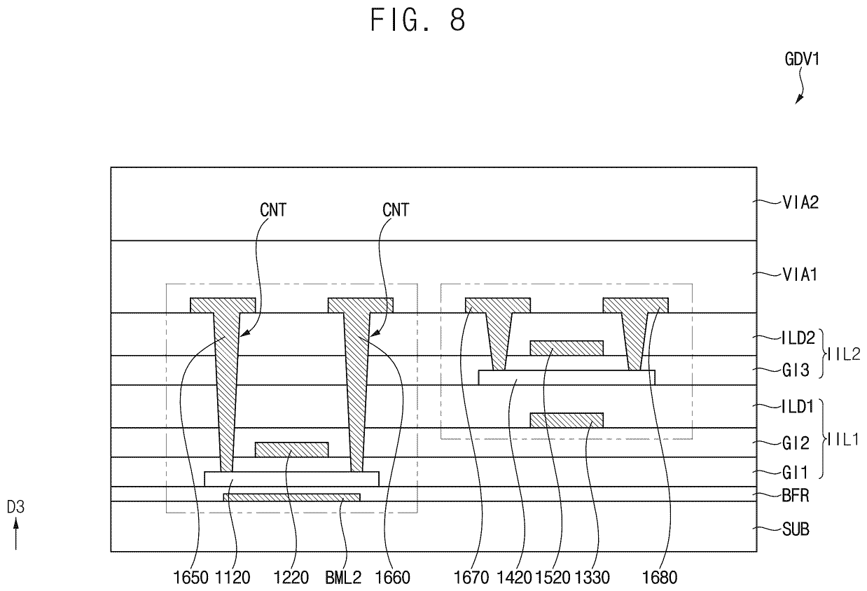

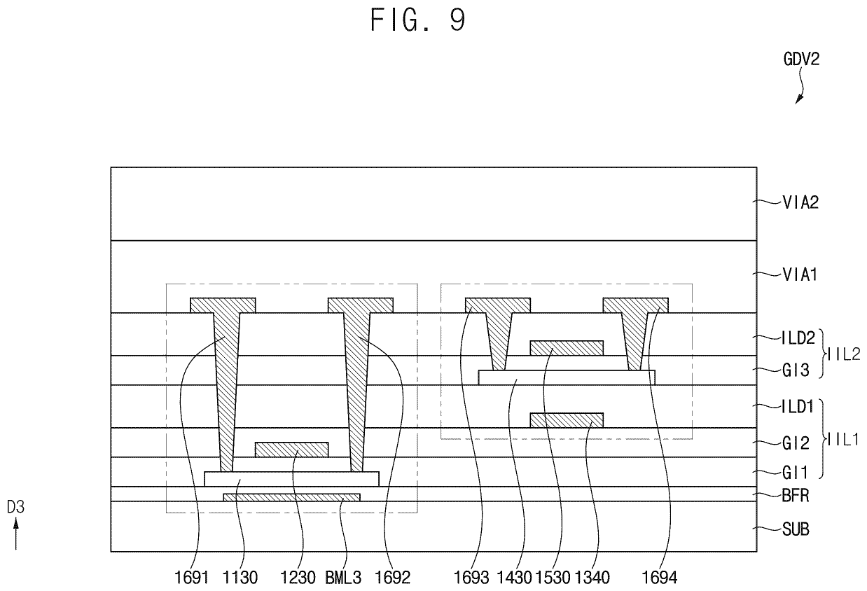

FIG. 7 is a cross-sectional view illustrating a pixel structure included in the display device of FIG. 6. FIG. 8 is a cross-sectional view illustrating a first gate driver included in the display device of FIG. 6. FIG. 9 is a cross-sectional view illustrating a second gate driver included in the display device of FIG. 6.

Referring to FIG. 7, the pixel structure PX located in the display area DA may include a pixel circuit part PC and a light-emitting diode OLED. The light-emitting diode OLED may be located on the pixel circuit part PC.

The pixel circuit part PC may include a substrate SUB, a first lower metal layer BML1, a buffer layer BFR, a first silicon semiconductor layer 1110, a first gate-insulating layer GI1, a first gate electrode 1210, a second gate-insulating layer GI2, a second gate electrode 1310, a third gate electrode 1320, a first interlayer insulating layer ILD1, a first oxide semiconductor layer 1410, a third gate-insulating layer GI3, a fourth gate electrode 1510, a second interlayer insulating layer ILD2, a first connection electrode 1610, a second connection electrode 1620, a third connection electrode 1630, a fourth connection electrode 1640, a first via insulating layer VIA1, a fifth connection electrode 1710, and a second via insulating layer VIA2.

The first gate-insulating layer GI1, the second gate-insulating layer GI2, and the first interlayer insulating layer ILD1 may be defined as a first inorganic insulating layer IIL1, and the third gate-insulating layer GI3 and the second interlayer insulating layer ILD2 may be defined as a second inorganic insulating layer IIL2.

The light-emitting diode OLED may include a pixel electrode ADE, a pixel-defining layer PDL, an emission layer EL, and a common electrode CTE.

The substrate SUB may include an insulating material such as glass, quartz, or plastic. In addition, the substrate SUB may be composed of a single layer or multiple layers by combining them.

The first lower metal layer BML1 may be located on the substrate SUB (“located on,” as used herein, may also refer to as “located above”). In one or more embodiments, the first lower metal layer BML1 may overlap the first silicon semiconductor layer 1110. The first lower metal layer BML1 may include metal, alloy, conductive metal oxide, transparent conductive material, etc. For example, the first lower metal layer BML1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The buffer layer BFR may be located on the substrate SUB. The buffer layer BFR may reduce or prevent metal atoms or impurities from diffusing into the first silicon semiconductor layer 1110 from the substrate SUB. In addition, the buffer layer BFR may control the rate of heat provision during the crystallization process for forming the first silicon semiconductor layer 1110.

The first silicon semiconductor layer 1110 may be located on the buffer layer BFR. In one or more embodiments, the first silicon semiconductor layer 1110 may include a silicon semiconductor. For example, the silicon semiconductor may include amorphous silicon, polycrystalline silicon, etc. For example, the first silicon semiconductor layer 1110 may include polycrystalline silicon formed by crystallizing the amorphous silicon.

The first gate-insulating layer GI1 may cover the first silicon semiconductor layer 1110, and may be located on the buffer layer BFR. The first gate-insulating layer GI1 may include an inorganic insulating material. For example, the first gate-insulating layer GI1 may include silicon oxide, silicon nitride, silicon oxynitride, etc.

The first gate electrode 1210 may be located on the first gate-insulating layer GI1, and may overlap the first silicon semiconductor layer 1110. The first gate electrode 1210 may include metal, alloy, conductive metal oxide, transparent conductive material, etc. For example, the first gate electrode 1210 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The second gate-insulating layer GI2 may cover the first gate electrode 1210, and may be located on the first gate-insulating layer GI1. The second gate-insulating layer GI2 may include an inorganic insulating material.

The second gate electrode 1310 may be located on the second gate-insulating layer GI2, and may overlap the first gate electrode 1210. The second gate electrode 1310 may include metal, alloy, conductive metal oxide, transparent conductive material, etc.

The third gate electrode 1320 may be located on the second gate-insulating layer GI2, and may include metal, alloy, conductive metal oxide, transparent conductive material, etc.

The first interlayer insulating layer ILD1 may cover the second and third gate electrodes 1310 and 1320, and may be located on the second gate-insulating layer GI2. The first interlayer insulating layer ILD1 may include an inorganic insulating material.

The first oxide semiconductor layer 1410 may be located on the first interlayer insulating layer ILD1, and may overlap the third gate electrode 1320. The first oxide semiconductor layer 1410 may include an oxide semiconductor. Examples of the oxide semiconductor that can be used as the first oxide semiconductor layer 1410 may include IGZO (InGaZnO), ITZO (InSnZnO), etc. In addition, the oxide semiconductor may further include indium (In), gallium (Ga), tin (Sn), zirconium (Zr), vanadium (V), hafnium (Hf), cadmium (Cd), germanium (Ge), chromium (Cr), titanium (Ti), and zinc (Zn). These can be used alone or in combination with each other.

The third gate-insulating layer GI3 may be located on the first oxide semiconductor layer 1410. The third gate-insulating layer GI3 may include an inorganic insulating material.

The fourth gate electrode 1510 may be located on the third gate-insulating layer GI3, and may overlap the first oxide semiconductor layer 1410. The fourth gate electrode 1510 may include metal, alloy, conductive metal oxide, transparent conductive material, etc.

The second interlayer insulating layer ILD2 may cover the fourth gate electrode 1510, and may be located on the third gate-insulating layer GI3. The second interlayer insulating layer ILD2 may include an inorganic insulating material.

The first and second connection electrodes 1610 and 1620 may be located on the second interlayer insulating layer ILD2, and may overlap the first silicon semiconductor layer 1110. The third and fourth connection electrodes 1630 and 1640 may be located on the second interlayer insulating layer ILD3, and may overlap the first oxide semiconductor layer 1410. The first to fourth connection electrodes 1610, 1620, 1630, and 1640 may include metal, alloy, conductive metal oxide, transparent conductive material, etc.

The first silicon semiconductor layer 1110, the first gate electrode 1210, the first connection electrode 1610, and the second connection electrode 1620 may correspond to any one of the PMOS transistors described with reference to FIG. 2.

The third gate electrode 1320, the first oxide semiconductor layer 1410, the fourth gate electrode 1510, the third connection electrode 1630, and the fourth connection electrode 1640 may correspond to any one of the NMOS transistors described with reference to FIG. 2.

The first via insulating layer VIA1 may cover the first to fourth connection electrodes 1610, 1620, 1630, and 1640, and may be located on the second interlayer insulating layer ILD2. The first via insulating layer VIA1 may include an organic insulating material. For example, the first via insulating layer VIA1 may include photoresist, polyacrylic resin, polyimide resin, acrylic resin, etc.

The fifth connection electrode 1710 may be located on the first via insulating layer VIA1, and may contact the first connection electrode 1610. The fifth connection electrode 1710 may include metal, alloy, conductive metal oxide, transparent conductive material, etc.

The second via insulating layer VIA2 may cover the fifth connection electrode 1710, and may be located on the first via insulating layer VIA1. The second via insulating layer VIA2 may include an organic insulating material.

The pixel electrode ADE may be located on the second via insulating layer VIA2, and may contact the fifth connection electrode 1710. The pixel electrode ADE may include metal, alloy, conductive metal oxide, transparent conductive material, etc.

The pixel-defining layer PDL may be located on the pixel electrode ADE and may expose the pixel electrode ADE. The pixel-defining layer PDL may include an organic insulating material.

The emission layer EL may be located on the pixel electrode ADE, and may include an organic light-emitting material.

The common electrode CTE may be located on the emission layer EL, and may include metal, alloy, conductive metal oxide, transparent conductive material, etc.

Referring to FIG. 8, the first gate driver GDV1 located in the first circuit area CA1 may include a second lower metal layer BML2, a second silicon semiconductor layer 1120, a fifth gate electrode 1220, a sixth gate electrode 1330, a second oxide semiconductor layer 1420, a seventh gate electrode 1520, and sixth to ninth connection electrodes 1650, 1660, 1670, and 1680. The substrate SUB, the buffer layer BFR, the first inorganic insulating layer IIL1, the second inorganic insulating layer IIL2, the first via insulating layer VIA1, and the second via insulating layer VIA2 may extend from the display area DA to the second line area LA2 and to the third line area LA3.

The second lower metal layer BML2 may be located at the same layer as the first lower metal layer BML1, and may include a metal, alloy, conductive metal oxide, transparent conductive material, etc.

The second silicon semiconductor layer 1120 may be located at the same layer as the first silicon semiconductor layer 1110, and may include a silicon semiconductor.

The fifth gate electrode 1220 may be located at the same layer as the first gate electrode 1210, and may overlap the second silicon semiconductor layer 1120.

The sixth gate electrode 1330 may be located at the same layer as the third gate electrode 1320.

The second oxide semiconductor layer 1420 may be located at the same layer as the first oxide semiconductor layer 1410, and may include an oxide semiconductor.

The seventh gate electrode 1520 may be located at the same layer as the fourth gate electrode 1510, and may overlap the second oxide semiconductor layer 1420.

The sixth connection electrode 1650 and the seventh connection electrode 1660 may be located on the second interlayer insulating layer ILD2. A contact hole(s) CNT penetrating the first inorganic insulating layer IIL1 and the second inorganic insulating layer IIL2 may be formed in the first gate driver GDV1. The sixth connection electrode 1650 and the seventh connection electrode 1660 may contact the second silicon semiconductor layer 1120 through the contact hole(s) CNT.

The eighth connection electrode 1670 and the ninth connection electrode 1680 may be located on the second interlayer insulating layer ILD2, and may contact the second oxide semiconductor layer 1420.

The second silicon semiconductor layer 1120, the fifth gate electrode 1220, the sixth connection electrode 1650, and the seventh connection electrode 1660 may correspond to any of the PMOS transistors described with reference to FIG. 3.

The sixth gate electrode 1330, the second oxide semiconductor layer 1420, the seventh gate electrode 1520, the eighth connection electrode 1670, and the ninth connection electrode 1680 may correspond to any one of the NMOS transistors described with reference to FIG. 3.

Referring to FIG. 9, the second gate driver GDV2 located in the second circuit area CA2 may include a third lower metal layer BML3, a third silicon semiconductor layer 1130, an eighth gate electrode 1230, a ninth gate electrode 1340, a third oxide semiconductor layer 1430, a tenth gate electrode 1530, and tenth to thirteenth connection electrodes 1691, 1692, 1693, and 1694.

The third lower metal layer BML3 may be located at the same layer as the first and second lower metal layers BML1 and BML2, and may include a metal, an alloy, a conductive metal oxide, a transparent conductive material, etc.

The third silicon semiconductor layer 1130 may be located at the same layer as the first and second silicon semiconductor layers 1110 and 1120, and may include a silicon semiconductor.

The eighth gate electrode 1230 may be located at the same layer as the first and fifth gate electrodes 1210 and 1220, and may overlap the third silicon semiconductor layer 1130.

The ninth gate electrode 1340 may be located at the same layer as the third and sixth gate electrodes 1320 and 1330.

The third oxide semiconductor layer 1430 may be located at the same layer as the first and second oxide semiconductor layers 1410 and 1420, and may include an oxide semiconductor.

The tenth gate electrode 1530 may be located at the same layer as the fourth and seventh gate electrodes 1510 and 1520, and may overlap the third oxide semiconductor layer 1430.

The tenth connection electrode 1691 and the eleventh connection electrode 1692 may be located in the second interlayer insulating layer ILD2, and may contact the third silicon semiconductor layer 1130.

The twelfth connection electrode 1693 and the thirteenth connection electrode 1694 may be located on the second interlayer insulating layer ILD2, and may contact the third oxide semiconductor layer 1130.

The third silicon semiconductor layer 1130, the eighth gate electrode 1230, the tenth connection electrode 1691, and the eleventh connection electrode 1692 may correspond to any of the PMOS transistors described with reference to FIG. 4.

The ninth gate electrode 1340, the third oxide semiconductor layer 1430, the tenth gate electrode 1530, the twelfth connection electrode 1693, and the thirteenth connection electrode 1694 may correspond to any one of the NMOS transistors described with reference to FIG. 4.

In one or more embodiments, the third gate driver GDV3 may have substantially the same circuit structure as the second gate driver GDV2 and may have a planar structure symmetrical to the second gate driver GDV2.

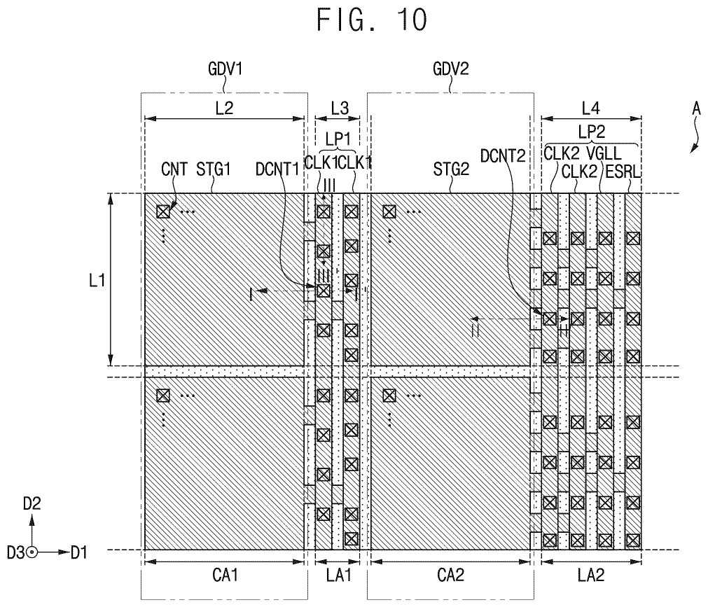

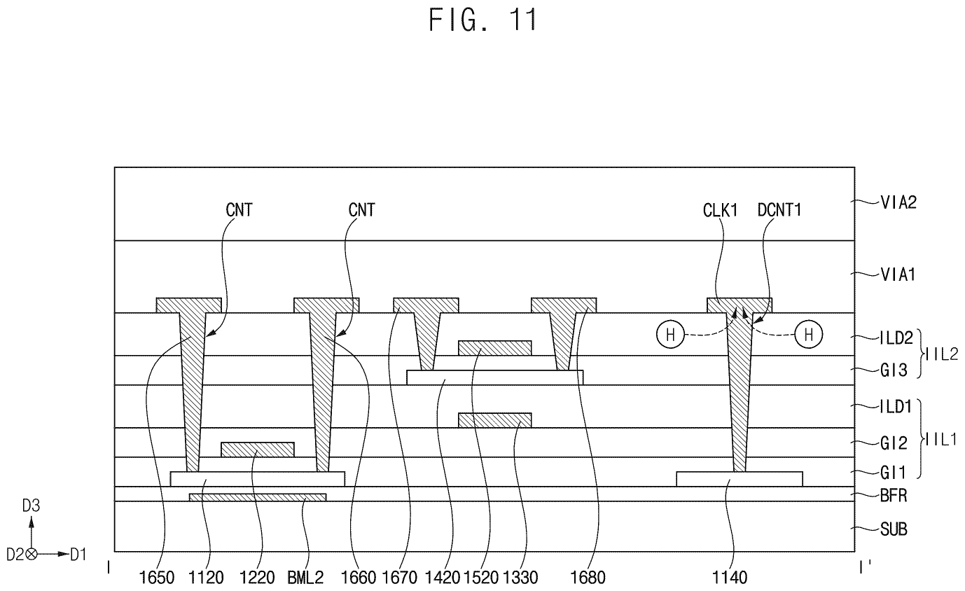

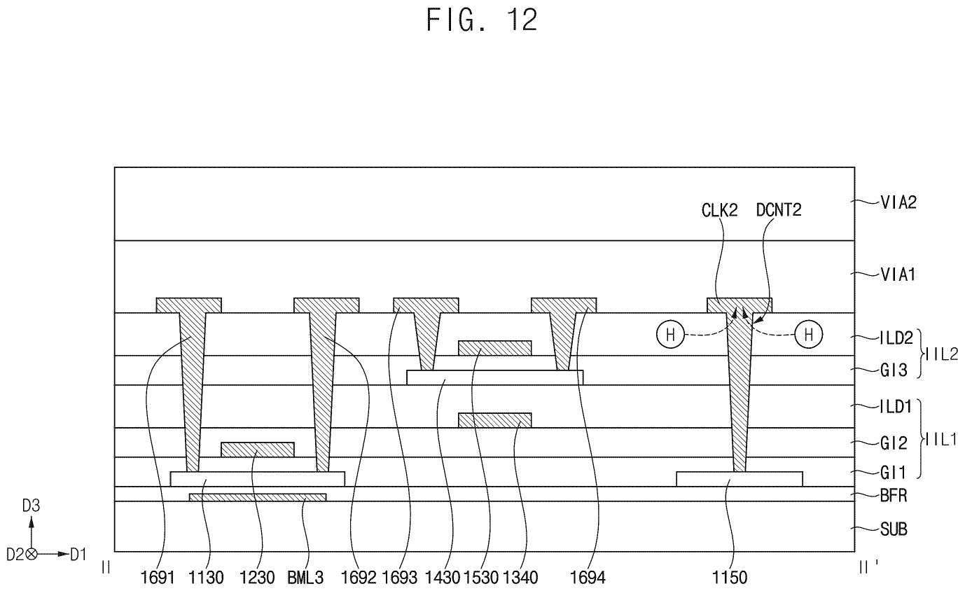

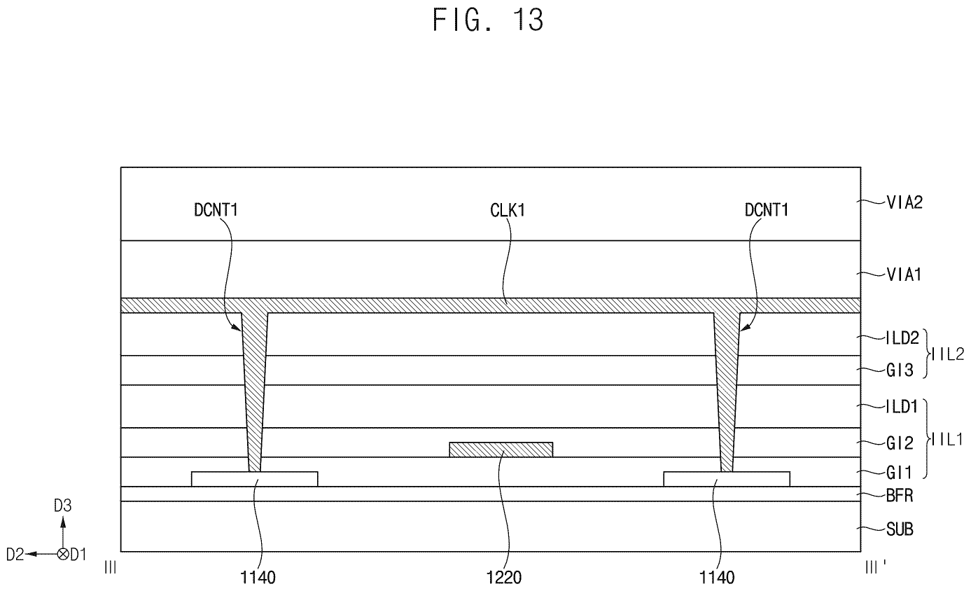

FIG. 10 is an enlarged view of a straight portion of FIG. 6. FIG. 11 is a cross-sectional view taken along the line I-I′ of FIG. 10. FIG. 12 is a cross-sectional view taken along the line II-II′ of FIG. 10. FIG. 13 is a cross-sectional view taken along the line III-III′ of FIG. 10.

Referring to FIG. 10, the first gate driver GDV1 may include the first stages STG1 arranged side by side in a second direction D2 that intersects the first direction D1. At least one contact hole CNT described with reference to FIG. 8 may be formed in each of the first stages STG1.

The first line part LP1 may include at least one first clock line CLK1, and the first clock line CLK1 may extend in the second direction D2. For example, as shown in FIG. 10, the first line part LP1 may include two first clock lines CLK1.

The first clock line CLK1 may be connected to each of the first stages STG1, and may provide a clock signal to each of the first stages STG1.

The second gate driver GDV2 may include the second stages STG2 arranged side by side in the second direction D2.

The second line part LP2 may include a reset signal wiring ESRL, a gate low voltage line VGLL, and at least one second clock line CLK2. For example, as shown in FIG. 10, the second line part LP2 may include two second clock line CLK2.

The second clock line CLK2 may be connected to each of the second stages STG2, and may provide a clock signal to each of the second stages STG2.

At least one first dummy contact hole DCNT1 may be formed in the first line part LP1. In one or more embodiments, the first dummy contact hole DCNT1 may overlap the first clock line CLK1. For example, the first dummy contact hole DCNT1 may be formed at substantially uniform intervals (e.g., as much as possible) while avoiding connection areas where each of the first stages STG1 and the first line part LP1 are connected.

The number of first dummy contact holes DCNT1 compared to the planar area of the first line part LP1 may correspond to the number of contact holes CNT compared to the planar area of each of the first stages STG1. For example, the planar area of each of the first stages STG1 may be calculated as the product of a first length L1 and a second length L2. Each of the first stages STG1 may have the same structure, and may be repeatedly arranged along the second direction D2, and the first length L1 may be defined as a vertical length of one first stage. The second length L2 may be a horizontal length of each of the first stages STG1, and may be substantially equal to a horizontal length of the first gate driver GDV1. In addition, the planar area of the first line part LP1 may be calculated as the product of the first length L1 and a third length L3. The first line part LP1 may include a plurality of lines arranged side by side in the first direction D1, and the third length L3 may be defined as a horizontal length in the first direction D1 from the leftmost line to the rightmost line.

In one or more embodiments, the number of the first dummy contact holes DCNT1 compared to the planar area of the first line part LP1 may be substantially equal to the number of the contact holes CNT compared to the planar area of each of the first stages STG1. That is, the number of the first dummy contact holes DCNT1 per unit area of the first line part LP1 may be substantially equal to the number of the contact holes CNT per unit area of each of the first stages STG1.

For example, the first length L1 of each of the first stages STG1 may be about 98.6 μm, and the second length L2 may be about 137 μm. In this case, the planar area of each of the first stages STG1 may be about 13508.2 μm². In addition, the number of contact holes CNT formed in each of the first stages STG1 may be about 73. Accordingly, the number of contact holes CNT compared to the planar area of each of the first stages STG1 may be about 0.0054/μm².

The first length L1 of the first line part LP1 may be about 98.6 μm, and the third length L3 may be about 17 μm. In this case, the planar area of the first line part LP1 may be about 1676.2 μm². In addition, the number of first dummy contact holes DCNT1 formed in the first line part LP1 may be about 9. Accordingly, the number of first dummy contact holes DCNT1 compared to the planar area of the first line part LP1 may be about 0.0054/μm².

At least one second dummy contact hole DCNT2 may be formed in the second line part LP2. In one or more embodiments, the second dummy contact hole DCNT2 may overlap the reset signal line ESRL, the gate low voltage line VGLL, and the second clock line CLK2. For example, the second dummy contact hole DCNT2 may be formed at equal intervals, to the extent possible, while avoiding connection areas where each of the second stages STG2 and the second wiring part LP2 are connected.

The number of second dummy contact holes DCNT2 compared to the planar area of the second line part LP2 may correspond to the number of contact holes CNT compared to the planar area of each of the first stages STG1.

For example, as described above, the number of contact holes CNT compared to the planar area of each of the first stages STG1 may be about 0.0054/μm².

The first length L1 of the second line part LP2 may be about 98.6 μm, and the fourth length L4 may be about 30 μm. In this case, the planar area of the second line part LP2 may be about 2958 μm². In addition, the number of second dummy contact holes DCNT2 formed in the second line part LP2 may be about 16. Accordingly, the number of second dummy contact holes DCNT2 compared to the planar area of the second line part LP2 may be about 0.0054/μm².

In one or more other embodiments, the number of the first dummy contact holes DCNT1 compared to the planar area of the first line part LP1 may be about 70% to about 130% of the number of the contact holes CNT compared to the planar area of each of the first stages STG1.

For example, as described above, the number of contact holes CNT compared to the planar area of each of the first stages STG1 may be about 0.0054/μm².

As an example, the number of first dummy contact holes DCNT1 formed in the first line part LP1 may be about 7. In this case, the number of first dummy contact holes DCNT1 compared to the planar area of the first line part LP1 may be about 0.0042/μm² (e.g., about 77%).

As another example, the number of first dummy contact holes DCNT1 formed in the first line part LP1 may be about 8. In this case, the number of first dummy contact holes DCNT1 compared to the planar area of the first line part LP1 may be about 0.0048/μm² (e.g., about 88%).

As another example, the number of first dummy contact holes DCNT1 formed in the first line part LP1 may be about 10. In this case, the number of first dummy contact holes DCNT1 compared to the planar area of the first line part LP1 may be about 0.0060/μm² (e.g., about 110%).

As another example, the number of first dummy contact holes DCNT1 formed in the first line part LP1 may be about 11. In this case, the number of first dummy contact holes DCNT1 compared to the planar area of the first line part LP1 may be about 0.0066/μm² (e.g., about 122%).

In addition, the number of the second dummy contact holes DCNT2 compared to the planar area of the second line part LP2 may be about 70% to about 130% of the number of the contact holes CNT compared to the planar area of each of the first stages STG1.

For example, as described above, the number of contact holes CNT compared to the planar area of each of the first stages STG1 may be about 0.0054/μm².

As an example, the number of second dummy contact holes DCNT2 formed in the second line part LP2 may be about 13. In this case, the number of second dummy contact holes DCNT2 compared to the planar area of the second line part LP2 may be about 0.0044/μm² (e.g., about 81%).

As another example, the number of second dummy contact holes DCNT2 formed in the second line part LP2 may be about 14. In this case, the number of second dummy contact holes DCNT2 compared to the planar area of the second line part LP2 may be about 0.0047/μm² (e.g., about 88%).

As another example, the number of second dummy contact holes DCNT2 formed in the second line part LP2 may be about 18. In this case, the number of second dummy contact holes DCNT2 compared to the planar area of the second line part LP2 may be about 0.0061/μm² (e.g., about 113%).

As another example, the number of second dummy contact holes DCNT2 formed in the second line part LP2 may be about 19. In this case, the number of second dummy contact holes DCNT2 compared to the planar area of the second line part LP2 may be about 0.0064/μm² (e.g., about 119%).

However, the above-described numerical range (e.g., about 70% to 130%) is only an example, and the number compared to the area of each of the first and second dummy contact holes DCNT1 and DCNT2 can be set appropriately based on the number compared to the area of the contact hole CNT.

In one or more embodiments, the reliability of each of the first stages STG1 may be determined to be good. In this case, as described above, the number of the first dummy contact holes DCNT1 and the number of the second dummy contact holes DCNT2 may be set to correspond to the number of the contact hole CNT compared to the planar area of each of the first stages STG1.

In one or more other embodiments, the reliability of each of the second stages STG2 may be determined to be good. In this case, the number of first dummy contact holes DCNT1 and the number of second dummy contact holes DCNT2 may be set to correspond to the number of contact holes compared to the planar area of each of the second stages STG2.

Referring to FIGS. 10 and 11, the first line part LP1 may further include a first etch stopper 1140. The first etch stopper 1140 may be located at the same layer as the first to third silicon semiconductor layers 1110, 1120, and 1130, and may include a silicon semiconductor. In one or more other embodiments, the first line part LP1 may not include the first etch stopper 1140.

The first inorganic insulating layer IIL1 and the second inorganic insulating layer IIL2 may further extend to the first line part LP1, and the first dummy contact hole DCNT1 may penetrate the first and second inorganic insulating layers IIL1 and IIL2. Accordingly, the first dummy contact hole DCNT1 may expose the first etch stopper 1140, and the first clock line CLK1 may contact the first etch stopper 1140.

In one or more embodiments, the first dummy contact hole DCNT1 may be adjacent to the second oxide semiconductor layer 1420. Accordingly, hydrogen contained in the second inorganic insulating layer IIL2 (e.g., the second interlayer insulating layer ILD2) may diffuse through the first dummy contact hole DCNT1. Therefore, the hydrogen may not diffuse into the second oxide semiconductor layer 1420. Accordingly, the negative shift of the threshold voltage of the NMOS transistor included in the first gate driver GDV1 can be reduced or prevented, and the reliability of the NMOS transistor can be improved.

Referring to FIGS. 10 and 12, the second line part LP2 may further include a second etch stopper 1150. The second etch stopper 1150 may be located at the same layer as the first to third silicon semiconductor layers 1110, 1120, and 1130, and may include a silicon semiconductor.

The first inorganic insulating layer IIL1 and the second inorganic insulating layer IIL2 may further extend to the second line part LP2, and the second dummy contact hole DCNT2 may penetrate the first and second inorganic insulating layers IIL1 and IIL2. Accordingly, the second dummy contact hole DCNT2 may expose the second etch stopper 1150, and the second clock line CLK2 may contact the second etch stopper 1150.

In one or more embodiments, the second dummy contact hole DCNT2 may be adjacent to the third oxide semiconductor layer 1430. Accordingly, hydrogen contained in the second inorganic insulating layer IIL2 (e.g., the second interlayer insulating layer ILD2) may diffuse through the second dummy contact hole DCNT2. Accordingly, the hydrogen may not diffuse into the third oxide semiconductor layer 1430. Accordingly, the negative shift of the threshold voltage of the NMOS transistor included in the second gate driver GDV2 can be reduced or prevented, and the reliability of the NMOS transistor can be improved.

Referring to FIGS. 10 and 13, for example, the fifth gate electrode 1220 of each of the first stages STG1 may be extended to overlap the first clock line CLK1. In this case, the first dummy contact hole DCNT1 may be formed to avoid the fifth gate electrode 1220, and the first etch stopper 1140 may be located in each first dummy contact hole DCNT1.

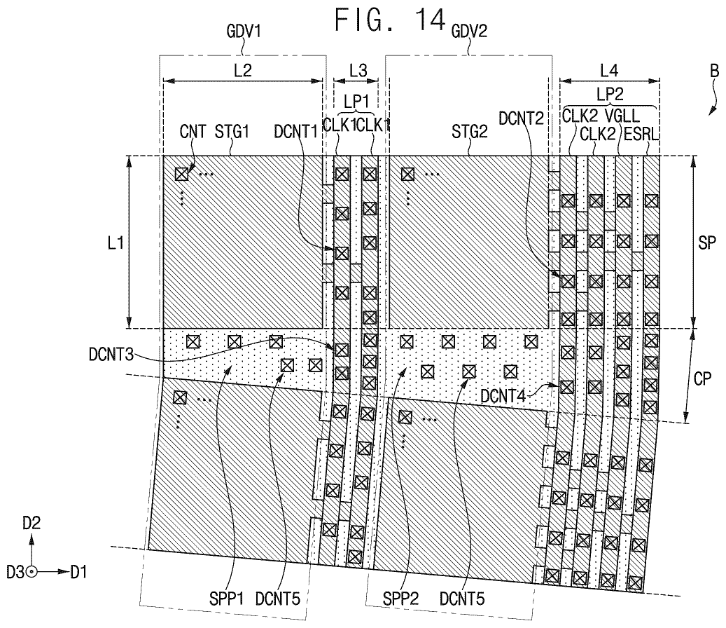

FIG. 14 is an enlarged view of a curved portion of FIG. 6.

Referring to FIG. 14, each of the first and second line parts LP1 and LP2 may include a straight portion SP (or a circuit portion) and a curved portion CP. For example, as shown in FIG. 6, to transmit a gate signal to the pixel structure located above and below the display area DA, the first gate driver GDV1, the first line part LP1, the second gate driver GDV2, and the second line part LP2 may be bent at the upper and lower sides as if surrounding the display area DA. Accordingly, as shown in FIG. 14, the curved portion CP may be defined in the first and second line parts LP1 and LP2. The first gate driver GDV1, the first line part LP1, the second gate driver GDV2, and the second line part LP2 located on the lower side of the display device 1000 are shown in FIG. 14, and the first gate driver GDV1, the first line part LP1, the second gate driver GDV2, and the second line part LP2 located on the upper side of the display device 1000 may also substantially correspond to this by having a curved portion.

A third dummy contact hole DCNT3 may be formed in the curved portion CP of the first line part LP1. The third dummy contact hole DCNT3 may be formed to be substantially the same as the first dummy contact hole DCNT1. For example, the third dummy contact hole DCNT3 may overlap the first clock line CLK1, and may penetrate the first and second inorganic insulating layers IIL1 and IIL2.

In one or more embodiments, the number of the third dummy contact holes DCNT3 compared to the planar area of (e.g., per unit area of) the curved portion CP may correspond to the number of the contact holes CNT compared to the planar area of (e.g., per unit area of) each of the first stages STG1. For example, the planar area of the curved portion CP may be about 926 μm², and the number of third dummy contact holes DCNT3 formed in the curved portion CP may be about 5. Accordingly, the number of third dummy contact holes DCNT3 compared to the planar area of the curved portion CP may be about 0.0054/μm².

Alternatively, the number of third dummy contact holes DCNT3 may be set to match the length of the curved portion CP in proportion to the length of the straight portion SP. For example, if the length of the curved portion CP is about half of the length of the straight portion SP, the number of third dummy contact holes DCNT3 may be set to about half of the number of the first dummy contact holes DCNT1. In addition, a fourth dummy contact hole DCNT4 may be formed in the curved portion CP of the second line part LP2. The fourth dummy contact hole DCNT4 may be formed to be substantially the same as the second dummy contact hole DCNT2.

In addition, spaces SPP1 and SPP2 may be defined between the stages, and a fifth dummy contact hole DCNT5 may be formed in the spaces SPP1 and SPP2. The fifth dummy contact hole DCNT5 may be formed to be substantially the same as the first dummy contact hole DCNT1. For example, an active pattern functioning as an etch stopper may be formed in the space portions SPP1 and SPP2, the fifth dummy contact hole DCNT5 may expose the active pattern, and the inside of the hole DCNT5 may be filled with the first via insulating layer VIA1.

The spaces SPP1 and SPP2 may include a first space SPP1 defined among the first stages STG1, and a second space SPP2 defined among the second stages STG2.

The number of fifth dummy contact holes DCNT5 compared to the planar area of the first space SPP1 may correspond to the number of contact holes CNT compared to the planar area of each of the first stages STG1. Meanwhile, the planar area of the first space SPP1 may not be constant depending on the curvature of the curved portion, the spacing between the first stages STG1, etc. In this case, an average distance between the contact holes CNT may be calculated, and the fifth dummy contact hole DCNT5 may have a distance corresponding to the average distance.

Similarly, the number of fifth dummy contact holes DCNT5 compared to the planar area of the second space SPP2 may correspond to the number of contact holes CNT compared to the planar area of each of the first stages STG1. Meanwhile, the planar area of the second space SPP2 may not be constant depending on the curvature of the curved portion, the spacing between the second stages STG2, etc. In this case, an average distance between the contact holes CNT may be calculated, and the fifth dummy contact hole DCNT5 may have a distance corresponding to the average distance.

Accordingly, the number of fifth dummy contact holes DCNT5 formed in the first space SPP1 may be different from the number of fifth dummy contact holes DCNT5 formed in the second space SPP2. For example, if the planar area of the first space SPP1 may be smaller than the planar area of the second space SPP2, the number of the fifth dummy contact hole DCNT5 formed in the first space SPP1 may be less than the number of fifth dummy contact holes DCNT5 formed in the second space SPP2.

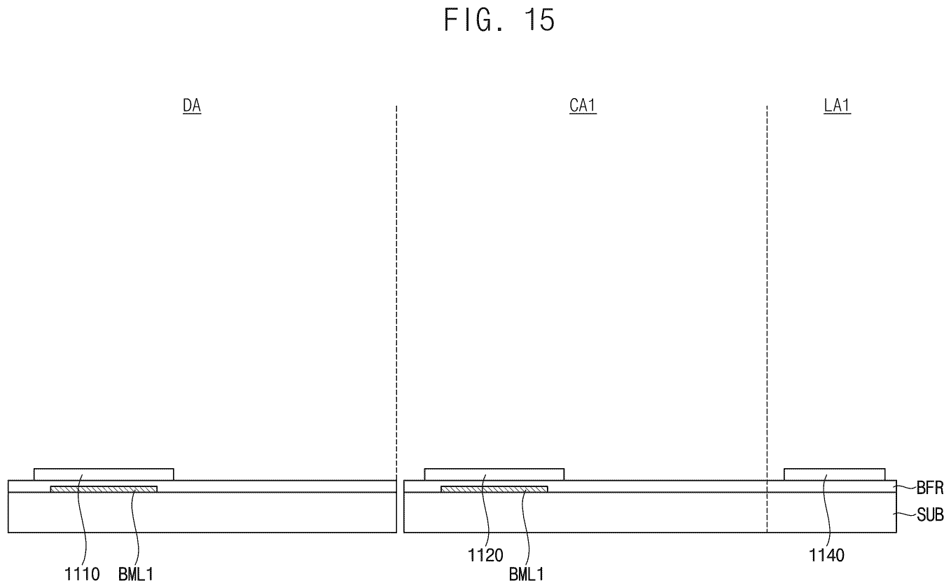

FIGS. 15 to 20 are cross-sectional views illustrating a method of manufacturing the display device of FIG. 6.

Referring to FIG. 15, the first silicon semiconductor layer 1110, the second silicon semiconductor layer 1120, and the first etch stopper 1140 may be formed together on the buffer layer BFR. The first silicon semiconductor layer 1110 may be formed in the display area DA, the second silicon semiconductor layer 1120 may be formed in the first circuit area CA1, and the first etch stopper 1140 may be formed in the first line area LA1.

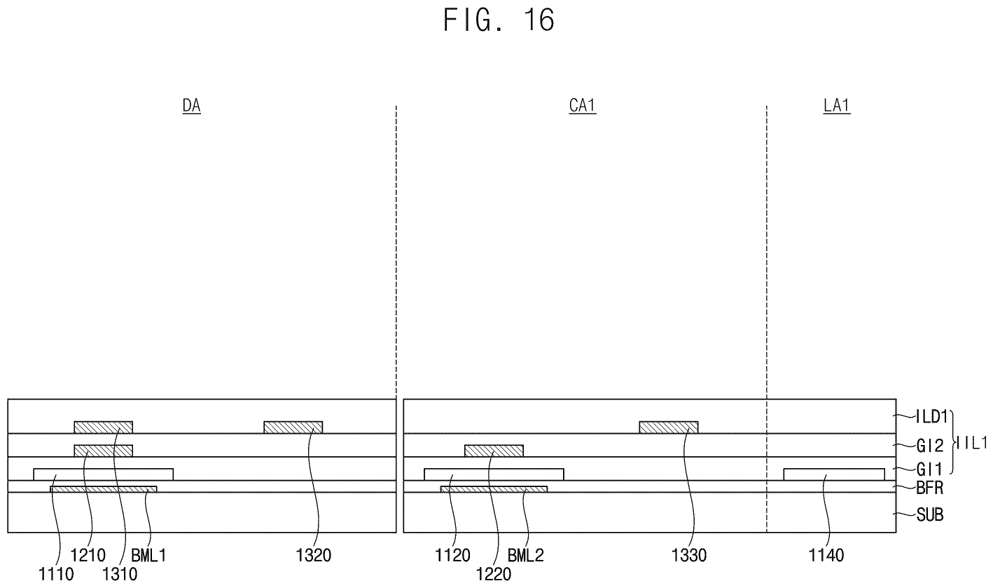

Referring to FIG. 16, the first inorganic insulating layer IIL1 may be formed on the first silicon semiconductor layer 1110, the second silicon semiconductor layer 1120, and the first etch stopper 1140. In detail, the first gate-insulating layer GI1, the first gate electrode 1210, the fifth gate electrode 1220, the second gate-insulating layer GI2, the second gate electrode 1310, the third gate electrode 1320, the sixth gate electrode 1330, and the first interlayer insulating layer IL1 may be formed sequentially.

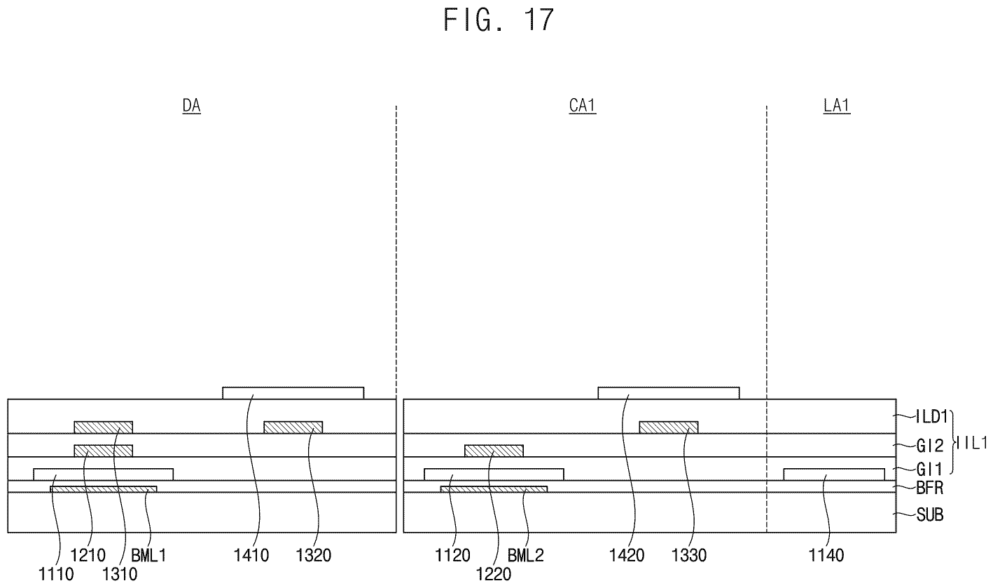

Referring to FIG. 17, the first and second oxide semiconductor layers 1410 and 1420 may be formed on the first inorganic insulating layer IIL1. The first oxide semiconductor layer 1410 may be formed in the display area DA, and the second oxide semiconductor layer 1420 may be formed in the first circuit area CA1.

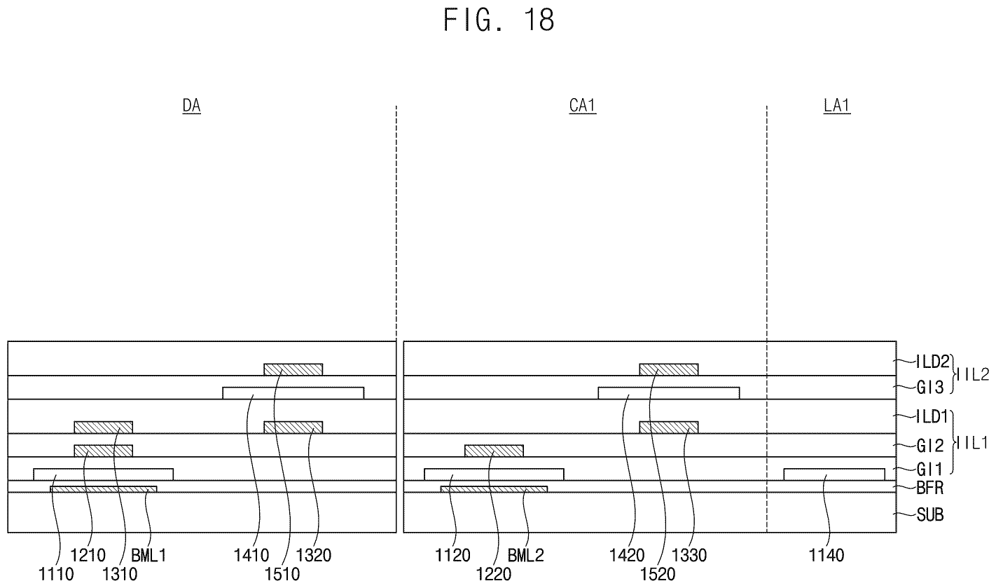

Referring to FIG. 18, the second inorganic insulating layer IIL2 may be formed on the first and second oxide semiconductor layers 1410 and 1420. In detail, the third gate-insulating layer GI3, the fourth gate electrode 1510, the seventh gate electrode 1520, and the second interlayer insulating layer ILD2 may be formed sequentially.

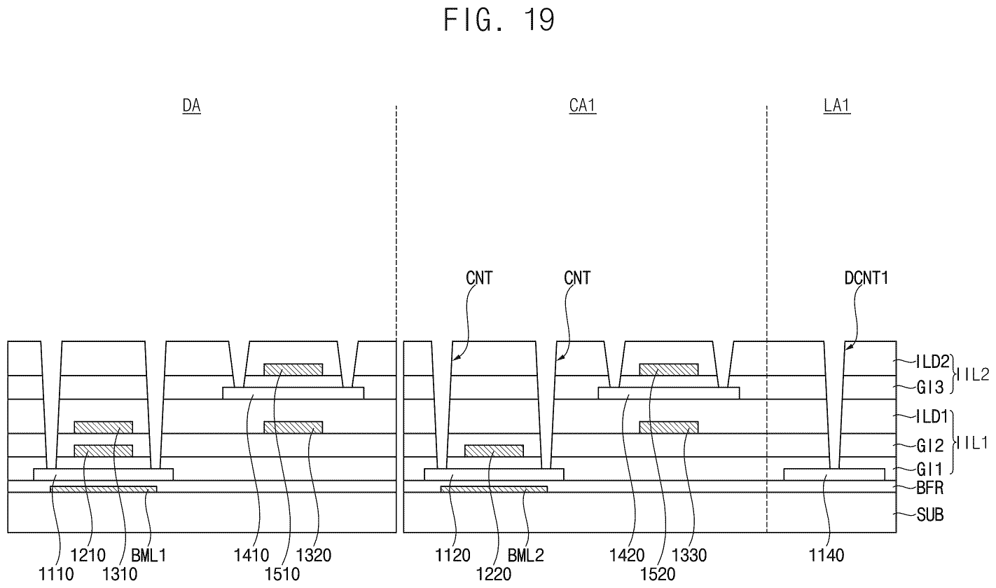

Referring to FIG. 19, a contact process may be performed. For example, the contact hole CNT may be formed in the first circuit area CA1, and the first dummy contact hole DCNT1 may be formed in the first line area LA1. The contact hole CNT and the first dummy contact hole DCNT1 may be formed together. In addition, contact holes may be further formed in the display area DA and the first circuit area CA1.

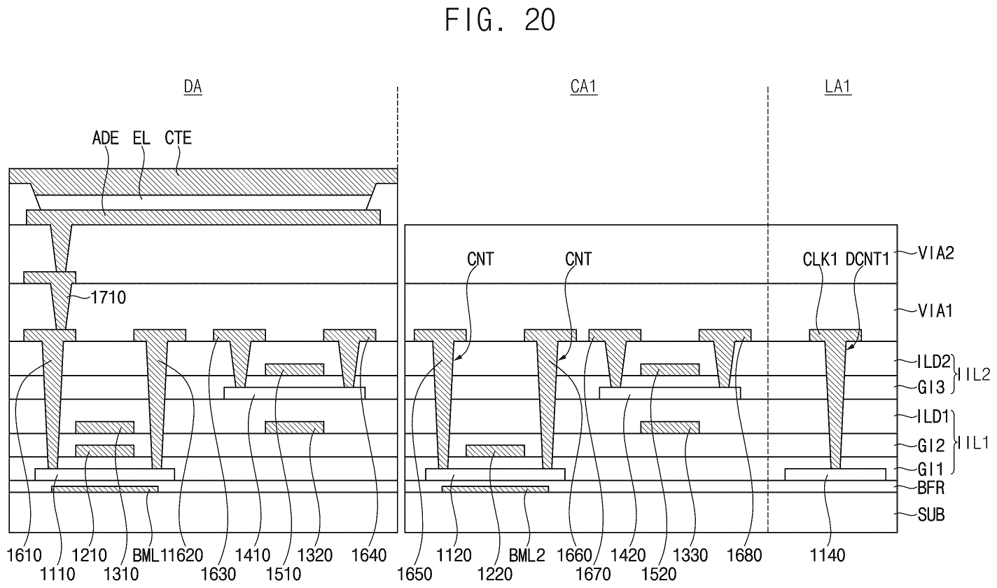

Referring to FIG. 20, the first to fourth connection electrodes 1610, 1620, 1630, and 1640, the sixth to ninth connection electrodes 1650, 1660, 1670, and 1680, and the first clock line CLK1 may be formed on the second interlayer insulating layer ILD2. The sixth and seventh connection electrodes 1650 and 1660 may contact the second silicon semiconductor layer 1120 through the contact hole CNT, and the first clock line CLK1 may contact the first etch stopper 1140 through the dummy contact hole DCNT1.

In addition, the first via insulating layer VIA1, the fifth connection electrode 1710, the second via insulating layer VIA2, the pixel electrode ADE, the pixel-defining layer PDL, the emission layer EL, and the common electrode CTE may be formed sequentially.

According to the above-described method of manufacturing the display device, the first dummy contact hole DCNT1 may be formed through the same contact process as the contact hole CNT. Accordingly, a separate contact process for forming the first dummy contact hole DCNT1 may not be added.

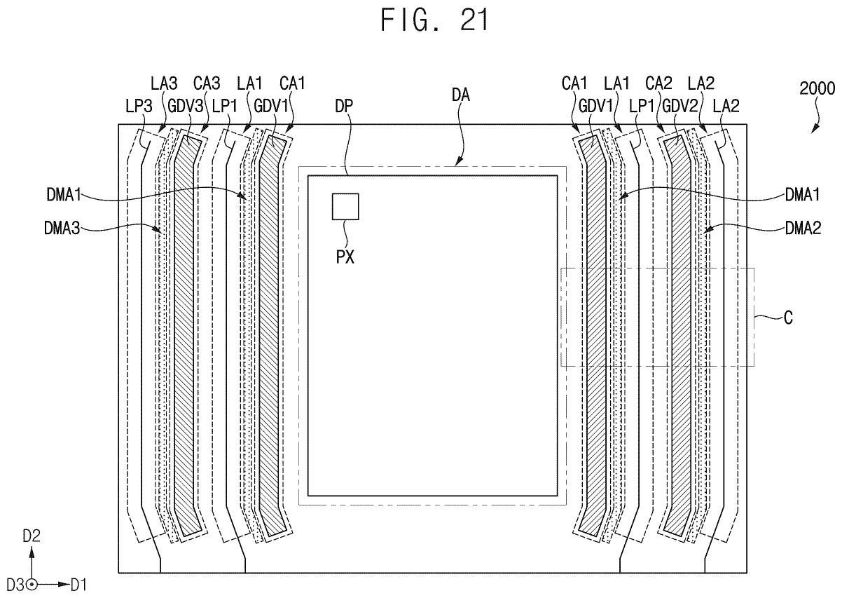

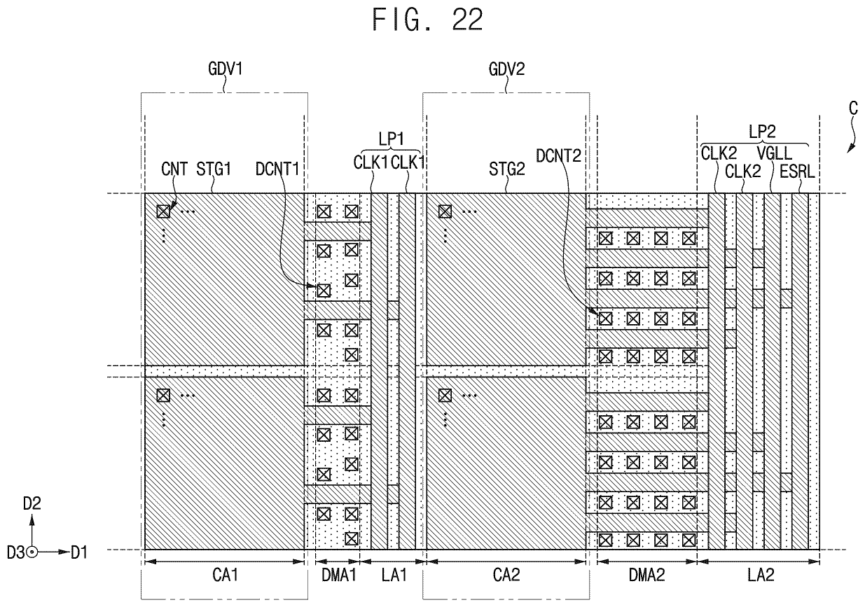

FIG. 21 is a plan view illustrating a display device according to one or more other embodiments of the present disclosure. FIG. 22 is an enlarged view of a straight portion of FIG. 21.

Referring to FIG. 21, the display device 2000 according to one or more other embodiments of the present disclosure may be substantially the same as the display device 1000 described with reference to FIG. 6, except for a first dummy area DMA1, a second dummy area DMA2, and a third dummy area DMA3.

In one or more embodiments, the first dummy area DMA1 may be located between the first circuit area CA1 and the first line area LA1. The second dummy area DMA2 may be located between the second circuit area CA2 and the second line area LA2. The third dummy area DMA3 may be located between the third circuit area CA3 and the third line area LA3.

However, the areas where the first to third dummy areas DMA1, DMA2, and DMA3 are located are not limited to the above. For example, the first dummy area DMA1 may be located between the display area DA and the first circuit area CA1. Alternatively, the first dummy area DA1 may be located between the first line area LA1 and the second circuit area CA2.

Referring to FIG. 22, a first dummy contact hole DCNT1 may be formed in the first dummy area DMA1. For example, the first dummy contact hole CNT1 may penetrate the first and second inorganic insulating layers IIL1 and IIL2 extending to the first dummy area DMA1. In addition, as described above, the number of the first dummy contact holes DCNT1 compared to the planar area of the first dummy area DMA1 may correspond to the number of contact holes CNT1 compared to the planar area of each of the first stages STG1.

A second dummy contact hole DCNT2 may be formed in the second dummy area DMA2. For example, the second dummy contact hole DCNT2 may penetrate the first and second inorganic insulating layers IIL1 and IIL2 extending into the second dummy area DMA2. In addition, as described above, the number of the second dummy contact holes DCNT2 compared to the planar area of the second dummy area DMA2 may correspond to the number of contact holes CNT2 compared to the planar area of each of the first stages STG1.

As the first dummy contact hole DCNT1 is formed in a separate first dummy area DMA1, the dummy contact hole may not be formed in the first line part LP1. Accordingly, the reliability of the lines located in the first line part LP1 can be improved.

Although certain embodiments and implementations have been described herein, other embodiments and modifications will be apparent from this description. Accordingly, the present disclosure are not limited to such embodiments, but rather to the broader scope of the appended claims and various obvious modifications and equivalent arrangements as would be apparent to a person of ordinary skill in the art.

What is claimed is:

1. A display device comprising:
a pixel circuit part comprising a first oxide semiconductor layer;
a first gate driver electrically connected to the pixel circuit part, and comprising a second oxide semiconductor layer at a same layer as the first oxide semiconductor layer; and
a first line part electrically connected to the first gate driver, and defining at least one first dummy contact hole adjacent to the second oxide semiconductor layer.

2. The display device of claim 1, wherein the first line part comprises at least one first clock line overlapping the first dummy contact hole, and for providing a clock signal to the first gate driver.

3. The display device of claim 1, further comprising a second gate driver electrically connected to the pixel circuit part, and comprising a third oxide semiconductor layer at a same layer as the second oxide semiconductor layer.

4. The display device of claim 3, further comprising a second line part adjacent to the second gate driver, electrically connected to the second gate driver, and defining at least one second dummy contact hole adjacent to the third oxide semiconductor layer.

5. The display device of claim 4, wherein the second line part comprises at least one second clock line overlapping the second dummy contact hole overlaps the second clock line, and for providing a clock signal to the second gate driver.

6. The display device of claim 1, wherein the first gate driver further comprises:
at least one first inorganic insulating layer under the second oxide semiconductor layer; and
at least one second inorganic insulating layer above the second oxide semiconductor layer,
wherein the first inorganic insulating layer and the second inorganic insulating layer extend to the first line part, and
wherein the first dummy contact hole penetrates the first and second inorganic insulating layers overlapping the first line part.

7. The display device of claim 6, wherein the pixel circuit part further comprises a first silicon semiconductor layer under the first oxide semiconductor layer,
wherein the first gate driver further comprises a second silicon semiconductor layer under the second oxide semiconductor layer, and
wherein the first line part comprises an etch stopper at a same layer as the second silicon semiconductor layer.

8. The display device of claim 7, wherein the first dummy contact hole exposes the etch stopper.

9. The display device of claim 8, wherein the first line part further comprises at least one first clock line contacting the etch stopper through the first dummy contact hole, and for providing a clock signal to the first gate driver.

10. The display device of claim 6, wherein the first gate driver is divided into first stages,
wherein one or more contact holes penetrating the first and second inorganic insulating layers is defined in the first stages, and
wherein a number of the first dummy contact holes per unit area of the first line part corresponds to a number of the contact holes per unit area of one of the first stages.

11. The display device of claim 10, wherein the number of the first dummy contact holes per unit area of the first line part is about 70% to about 130% of the number of the contact holes per unit area of each of the first stages.

12. The display device of claim 10, further comprises:
a second gate driver divided into second stages; and
a second line part electrically connected to the second gate driver,
wherein the first inorganic insulating layer and the second inorganic insulating layer extend to the second gate driver and to the second line part,
wherein at least one second dummy contact hole is defined in the second line part, and penetrates the first and second inorganic insulating layers overlapping the second line part, and
wherein a number of the second dummy contact holes per unit area of the second line part corresponds to the number of the contact holes per unit area of each of the first stages.

13. The display device of claim 1, wherein the first line part comprises a straight portion, and comprises a curved portion defining a third dummy contact hole.

14. The display device of claim 13, wherein the first gate driver further comprises:
at least one first inorganic insulating layer under the second oxide semiconductor layer; and
at least one second inorganic insulating layer above the second oxide semiconductor layer,
wherein the first inorganic insulating layer and the second inorganic insulating layer extend to the first line part, and
wherein the third dummy contact hole penetrates the first and second inorganic insulating layers overlapping the curved portion.

15. The display device of claim 14, wherein the first gate driver is divided into first stages,
wherein at least one contact hole penetrating the first and second inorganic insulating layers is defined in the first stages, and
wherein a number of the third dummy contact holes per unit area of the curved portion corresponds to the number of the contact holes per unit area of the first stages.

16. The display device of claim 1, wherein the pixel circuit part further comprises a first silicon semiconductor layer under the first oxide semiconductor layer, and
wherein the first gate driver further comprises a second silicon semiconductor layer at a same layer as the first silicon semiconductor layer.

17. The display device of claim 1, further comprising a second gate driver electrically connected to the pixel circuit part, and comprising a third oxide semiconductor layer at a same layer as the second oxide semiconductor layer,
wherein the first gate driver is configured to provide a gate compensation signal to the pixel circuit part, and
wherein the second gate driver is configured to provide a gate bias signal to the pixel circuit part.

18. The display device of claim 1, further comprising a second gate driver electrically connected to the pixel circuit part, and comprising a third oxide semiconductor layer at a same layer as the second oxide semiconductor layer,
wherein the first gate driver is configured to provide a gate compensation signal to the pixel circuit part, and
wherein the second gate driver is configured to provide an emission management signal to the pixel circuit part.

19. A display device comprising:
a first oxide semiconductor layer overlapping a display area;
a second oxide semiconductor layer at a same layer as the first oxide semiconductor layer, and overlapping a circuit area adjacent to the display area; and
at least one inorganic insulating layer overlapping the circuit area, and a line area adjacent to the circuit area and defining at least one dummy contact hole, and
wherein the dummy contact hole is adjacent to the second oxide semiconductor layer, and is defined by the inorganic insulating layer.

20. The display device of claim 19, further comprising at least one clock line overlapping the line area, and overlapping the dummy contact hole.

21. The display device of claim 19, wherein the inorganic insulating layer comprises:
a first inorganic insulating layer under the second oxide semiconductor layer; and
a second inorganic insulating layer above the second oxide semiconductor layer,
wherein the first inorganic insulating layer and the second inorganic insulating layer extend to the line area, and
wherein the dummy contact hole penetrates the first and second inorganic insulating layers overlapping the line area.

22. The display device of claim 21, further comprising:
a first silicon semiconductor layer overlapping the display area, and under the first oxide semiconductor layer;
a second silicon semiconductor layer overlapping the circuit area, and under the second oxide semiconductor layer; and
an etch stopper overlapping the line area, and at a same layer as the second silicon semiconductor layer.

23. The display device of claim 22, wherein the dummy contact hole exposes the etch stopper.

24. The display device of claim 23, further comprising at least one clock line overlapping the line area, and contacting the etch stopper through the dummy contact hole.
